(19) United States
(12) Patent Application Publication
(10) Pub. No.: US 2014/0252542 A1
(43) Pub. Date: Sep. 11, 2014

(54) Structure and Method for an Inductor With Metal Dummy Features

(71) Applicant: Taiwan Semiconductor Manufacturing Company, Ltd., Hsin-Chu (TW)

(72) Inventors: Hsiao-Chun Lee, Chiayi City (TW); Victor Chiang Liang, Hsinchu City (TW); Chi-Feng Huang, Zhubei City (TW)

(21) Appl. No.: 13/792,306

(22) Filed: Mar. 11, 2013

(51) Int. Cl. H01L 49/02

(52) U.S. Cl. CPC H01L 28/10
USPC 257/531; 438/381

(57) ABSTRACT

The present disclosure provides a semiconductor device. The semiconductor device includes an inductor formed on a substrate and configured to be operable with a current of a frequency; and dummy metal features configured between the inductor and the substrate, the dummy metal features having a first width less than 2 times of a skin depth associated with the frequency.

### BACKGROUND

The semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed. In the course of integrated circuit evolution, functional density (i.e., the number of interconnected devices per chip area) has generally increased while geometry size (i.e., the smallest component (or line) that can be created using a fabrication process) has decreased.

Various active or passive electronic components can be formed on a semiconductor IC. For example, an inductor may be formed as a passive electronic component. As device sizes continue to decrease for even higher frequency applications, existing inductor structures may encounter problems. For example, dummy features are inserted to enhance the fabrication. However, dummy filling narrows the back-end of line process window. Other issues include moisture penetration for advanced technology with low k dielectric material, and degradation of the inductor performance.

Therefore, a structure of an inductor and a method making the same are needed to address the above issues.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a top view of a semiconductor structure having an inductor constructed according to aspects of the present disclosure in one or more embodiments.

FIG. 2 is a sectional view of the semiconductor structure of FIG. 1 constructed according to aspects of the present disclosure in one or more embodiments.

FIG. 3 is a top view of a semiconductor structure having an inductor constructed according to aspects of the present disclosure in other one or more embodiments.

FIG. 4 is a sectional view of the semiconductor structure of FIG. 3 constructed according to aspects of the present disclosure in other one or more embodiments.

FIG. 5 is a top view of a semiconductor structure having an inductor constructed according to aspects of the present disclosure in other one or more embodiments.

FIG. 6 is a sectional view of the semiconductor structure of FIG. 5 constructed according to aspects of the present disclosure in other one or more embodiments.

FIG. 7 is a top view of the semiconductor structure having an inductor constructed according to aspects of the present disclosure in various embodiments.

FIG. 8 is a diagram illustrating a size vs frequency relationship constructed according to aspects of the present disclosure in one embodiment.

FIG. 9 is a flowchart of method for making a semiconductor device having an inductor.

FIGS. 10 and 14 are perspective views of a semiconductor structure, in portion, constructed according to aspects of the present disclosure in various embodiments.

FIGS. 11, 12, 13, 15 and 16 are top views of a semiconductor structure, in portion, constructed according to aspects of the present disclosure in various embodiments.

FIG. 17 is a diagram illustrating simulation of dummy fill constructed according to aspects of the present disclosure in various embodiments.

FIG. 18 is a diagram illustrating frequency dependence constructed according to aspects of the present disclosure in various embodiments.

### DETAILED DESCRIPTION

It is understood that the following disclosure provides many different embodiments, or examples, for implementing different features of various embodiments. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

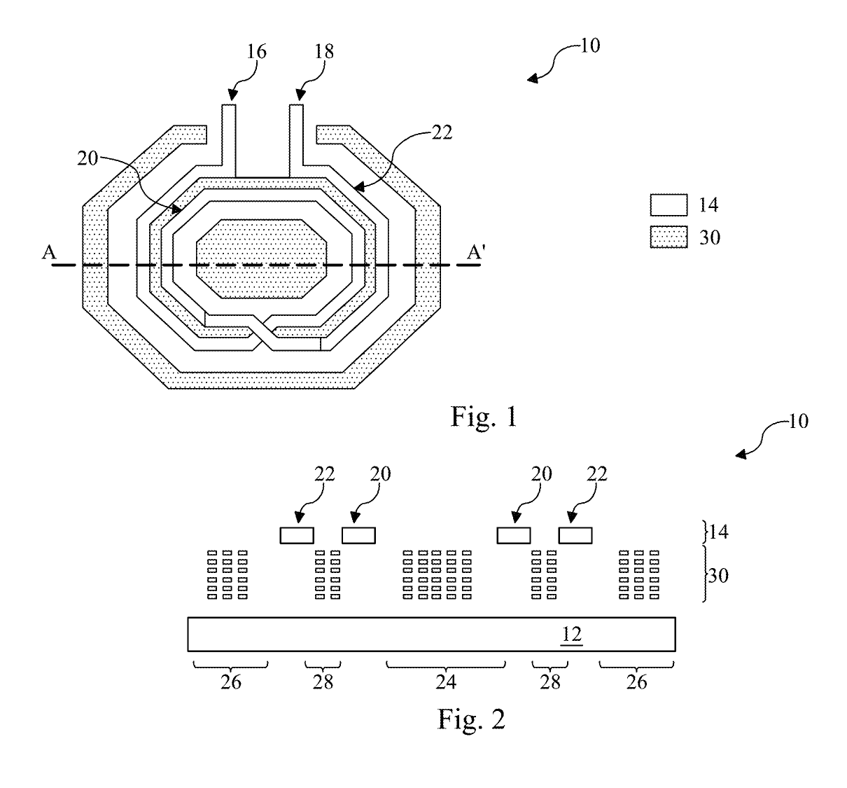

FIG. 1 is a top view of a semiconductor structure 10 having an inductor and FIG. 2 is a sectional view of the semiconductor structure 10 taken at the dashed line AA′. The semiconductor structure 10 is described with reference to FIGS. 1 and 2.

The semiconductor structure 10 includes a substrate 12, such as a semiconductor substrate. In the present example, the substrate 12 is a silicon substrate. In other examples, the substrate 12 may alternatively or additionally includes other suitable semiconductor material, such as germanium, silicon germanium, silicon carbide, or gallium arsenic.

The semiconductor structure 10 includes an inductor 14 having conductive features (wires) configured to form a coil with one or more turns. The inductor 12 is a two terminal device. The two terminals 16 and 18 are configured to be electrically connected to power or signal lines for proper operation during applications.

The conductive features of the inductor 14 are various metal features (also referred to as inductor metal features) configured to form a coil with multiple turns. For example, the conductive features of the inductor 14 include copper, aluminum, tungsten, other suitable metal materials or combinations thereof. In the present embodiment, the conductive features of the inductor 14 are configured to form two turns, first turn (inside turn) 20 and second turn (outside turn) 22. In a top view, various regions are defined thereby. An inside region 24 is a region enclosed inside of the inductor 14. Specifically, the inside region 24 is an enclosed region defined by the inside turn 20. An outside region 26 is a region outside of the inductor 14. Specifically, the outside region 26 is a region outside of the outside turn 22. For example, the outside region 26 is defined as a region outside of the outside turn 22 in a certain range. A gap region 28 is defined as a region between the inside turn 20 and the outside turn 22.

In various examples, other devices, such as transistors, diodes, sensors, memory device, resistor, capacitor, and/or light emitting diode, are formed on the substrate 12 and are coupled with the inductor 12 to form an integrated circuit (IC) according various applications.

The semiconductor structure 10 includes dummy features 30 formed on the substrate 12 and are underlying the inductor 14. Particularly, the dummy features 30 are configured between the substrate and the inductor 14 as illustrated in FIG. 2. The dummy features 30 are conductive features and electrically floating. The dummy features 30 are designed and configured to enhance the fabrication quality and device performance, especially to improve the back end of line uniformity and reliability. In the present embodiment, the dummy features 30 are metal features, therefore also referred to as dummy metal features. For example, the dummy features 30 include copper, aluminum, tungsten, other suitable metal materials or combinations thereof.

In the top view, the dummy features 30 are disposed in the first region 24 and the second region 26. In one embodiment, the dummy features 30 are additionally disposed in the gap region 28 to further increase the pattern density.

The metal features of the inductor 14 have a first thickness and the dummy features 30 have a second thickness that is substantially less than the first thickness. The metal features of the inductor 14 have a first width and the dummy features 30 have a second width that is substantially less than the first width.

Especially, the dummy features 30 are designed with various dimensions according to the skin effect to avoid or reduce the eddy current. The inductor 14 is designed to be operable to work with a signal (current) of a frequency “f”. The skin depth “δ” is determined by the operation frequency f, or is a function of the frequency f as δ(f). Particularly, the skin depth is defined as δ=1/(πfμσ)^{1/2}, where σ is the resistivity of the dummy features and μ is the absolute magnetic permeability of the dummy features 30. The second width w is determined as less than 2 times skin depth, or w<2×δ(f). Furthermore, according to the present embodiment, the second thickness T is less than 2 times skin depth, or T<2×δ(f) according to one embodiment.

The dummy features 30 are designed to have a shape according to fill area or other factors, such as pattern density. In various embodiments, the dummy features 30 are designed to have a shape as rectangle, cross, a fence structure without closed loop (to avoid the eddy current), or combinations thereof. In one example, the dummy features filled in a narrow region are designed as rectangle. In another example, the dummy features filled in a large and wide region are designed to have a cross shape. In another example, the dummy features filled in a region for higher pattern density are designed to have a fence structure.

The dummy features 30 are designed to have a configuration according to the expected pattern density, such as the patterned density determined by the design rule of the inductor. In one embodiment, the dummy features 30 are arranged to have a subset disposed in the gap region 28. In another embodiment, the dummy features 30 are arranged to have a plurality layers stacked on each other. In various cases, the dummy features 30 are separated and isolated from each other by dielectric material. As one example, the dummy features 30 are configured in 6 layers as illustrated in FIG. 2.

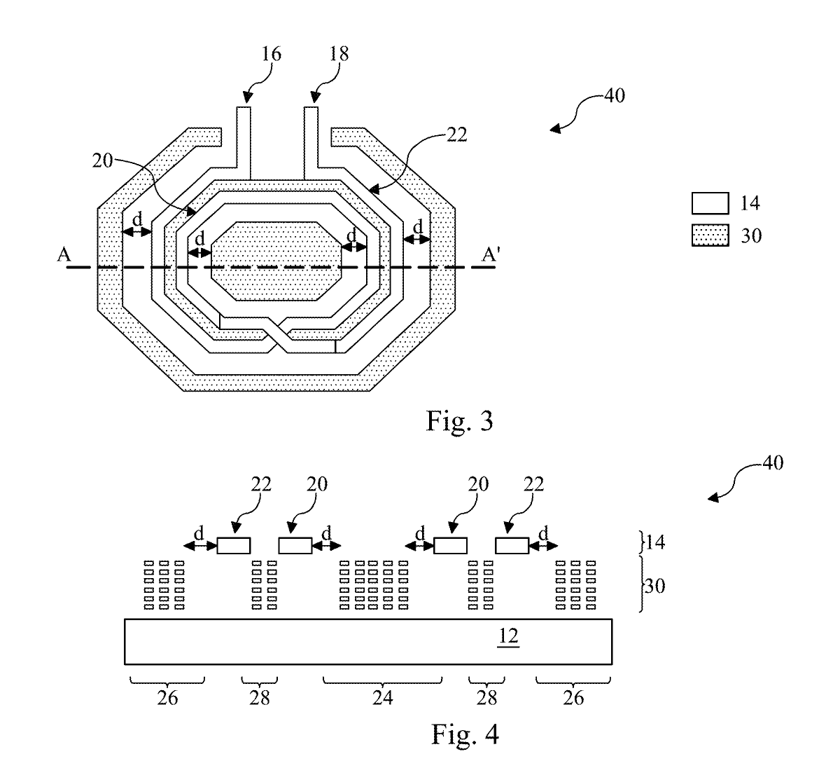

FIG. 3 is a top view of a semiconductor structure 40 having an inductor and FIG. 4 is a sectional view of the semiconductor structure 40 taken at the dashed line AA′. The semiconductor structure 40 is described with reference to FIGS. 3 and 4. The semiconductor structure 40 is similar to the semiconductor structure 10 of FIGS. 1 and 2. The semiconductor structure 40 includes the inductor 14 and the dummy features 30. The similar descriptions are not repeated for simplicity.

Particularly, the dummy features 30 includes a first subset disposed in the inside region 24 and a second subset disposed in the outside region 26, and further includes a third subset disposed in the gap region 28. The first subset of the dummy features are arranged to have a first clearance to the inductor 14 and the second subset of the dummy features are arranged to have a first clearance to the inductor 14, to reduce and minimize the parasitic effect. The clearance is defined as the horizontal distance between the dummy features and the inductor. In the present embodiment, the first clearance and second clearance are equal, labeled as “d” in FIGS. 3 and 4. The clearance d is determined according to the parasitic effect, which may be set up in the design rule. In the present example, the clearance d is greater than 10 micron.

Due to much less magnetic field in the gap region 28, the third subset of the dummy features 30 is further disposed in the gap region 28 for additional pattern density tuning. The regions where the inductor wires are displaced are defined as forbidden areas. The dummy features 30 are not displaced in the forbidden areas directly underlying the inductor wires to minimize the parasitic effect. In the present embodiment, the forbidden areas includes a first forbidden region between the inside region 26 and the gap region 28 and includes a second forbidden region between the gap region 28 and the outside region 26. The conductive features of the indie turn 20 are displaced in the first forbidden region and the conductive features of the outside turn 22 are displaced in the second forbidden region. Proper arrangement of the dummy features 30 with above considerations is able to optimize the dummy configuration to meet minimum logic metal density rule.

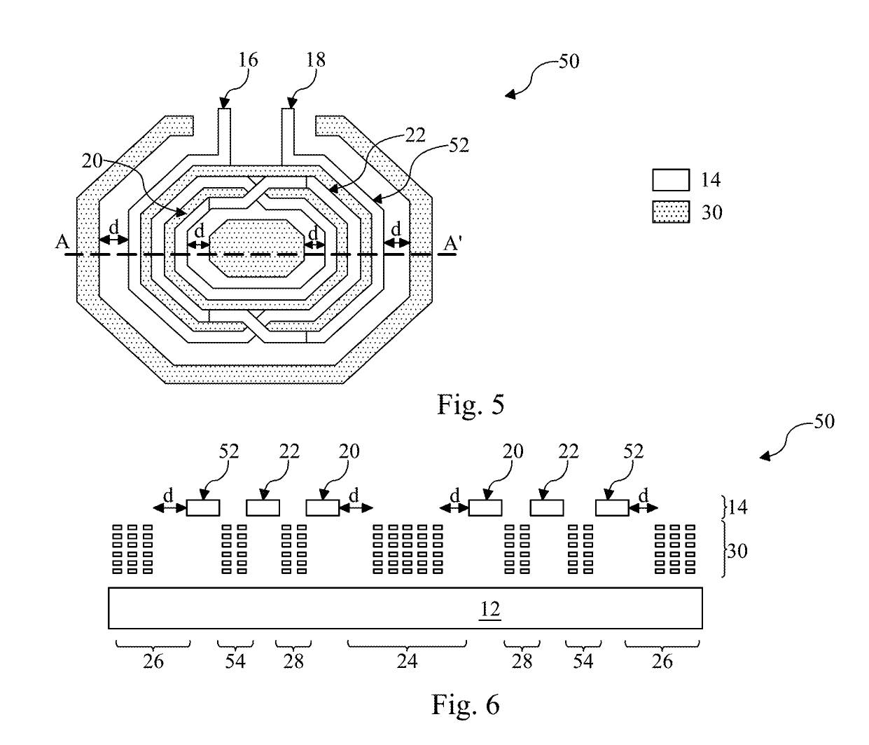

FIG. 5 is a top view of a semiconductor structure 50 having an inductor and FIG. 4 is a sectional view of the semiconductor structure 50 taken at the dashed line AA′. The semiconductor structure 50 is one embodiment of the semiconductor structure 10 of FIG. 1 and is similar to the semiconductor structure 40 of FIGS. 3 and 4. However, in the semiconductor structure 50, the inductor 14 is configured to form a coil with three turns, first turn 20, second turn 22 and third turn 52. In the present case, the first turn 20 is an inside turn, the second turn 22 is a middle turn and the third turn 52 is an outside turn.

In a top view, various regions are defined by the conductive features of the inductor 14. A inside region 24 is a region enclosed inside of the inductor 14. Specifically, the inside region 24 is an enclosed region defined by the first turn 20. An outside region 26 is a region outside of the inductor 14. Specifically, the outside region 26 is a region outside of the third turn 52. For example, the outside region 26 is defined as a region outside of the third turn 52 in a certain range. A first gap region 28 is defined as a region between the first turn 20 and the second turn 22. A second gap region 54 is defined as a region between the second turn 22 and the third turn 52.

The forbidden areas are defined as those regions where the conductive features of the inductor 14 located. Particularly, a first forbidden area is a region between the inside region 24 and the first gap region 28, and is where the first turn 20 of the inductor is located. A second forbidden area is a region between the first gap region 28 and the second gap region 54, and is where the second turn 22 of the inductor is located. A third forbidden area is a region between the second gap region 54 and the outside region 26, and is where the third turn 52 of the inductor is located.

In the top view, the dummy features 30 are disposed in the first region 24 and the second region 26. In one embodiment, the dummy features 30 are additionally disposed in the gap regions 28 and 54 to further increase the pattern density. The dummy features 30 are not disposed in the forbidden areas to minimize the parasitic effect. Furthermore, according to one embodiment, the dummy features 30 are disposed in the inside region 24 and the outside region 26 with a clearance d such that the parasitic effect is controlled to an acceptable range.

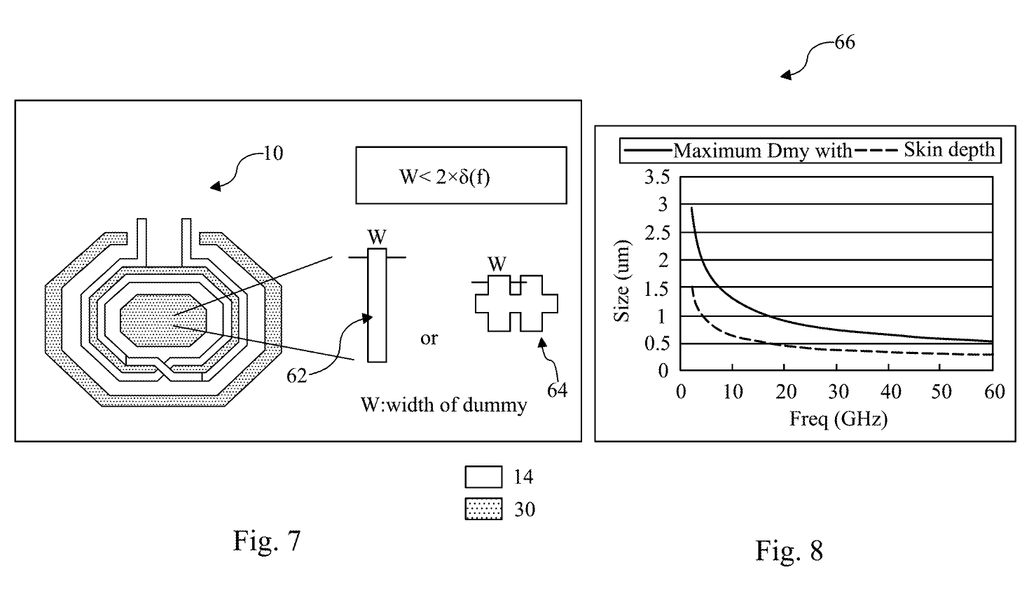

FIG. 7 is a top view of the semiconductor structure 10 and FIG. 8 is a diagram illustrating a size vs frequency relationship constructed according to aspects of the present disclosure in one embodiment. As noted above, the dimensions of the dummy features 30 are determined based on the skin effect and are further described with reference to FIGS. 7 and 8. The semiconductor 10 includes an inductor 14 configured to form a coil with multiple turns and dummy features 30 disposed underlying the inductor 14 in the inside region, outside region and gap region(s).

The dummy features 30 are designed with proper shape according filling regions. In various embodiments, the dummy features 30 are designed to have a shape as rectangle, cross, a fence structure without closed loop (to avoid the eddy current), or combinations thereof. In one example, the dummy features filled in a narrow region are designed as rectangle 62. In another example, the dummy features filled in a large and wide region are designed to have a cross shape. In another example, the dummy features filled in a region for higher pattern density are designed to have a fence structure 64.

Especially, the dummy features 30 are designed with various dimensions according to the skin effect to avoid or reduce the eddy current. The inductor 14 is designed to be operable to work with a signal (current) of a frequency “f”. The skin depth “δ” is determined by the operation frequency f, or is a function of the frequency f as δ(f). Each dummy feature includes an elongated segment having a width “w”, as illustrated in FIG. 7. The width w is designed to be less than 2 times skin depth, or w<2×δ(f). Furthermore, according to the present embodiment, the thickness T of the dummy features 30 is less than 2 times skin depth, or T<2×δ(f).

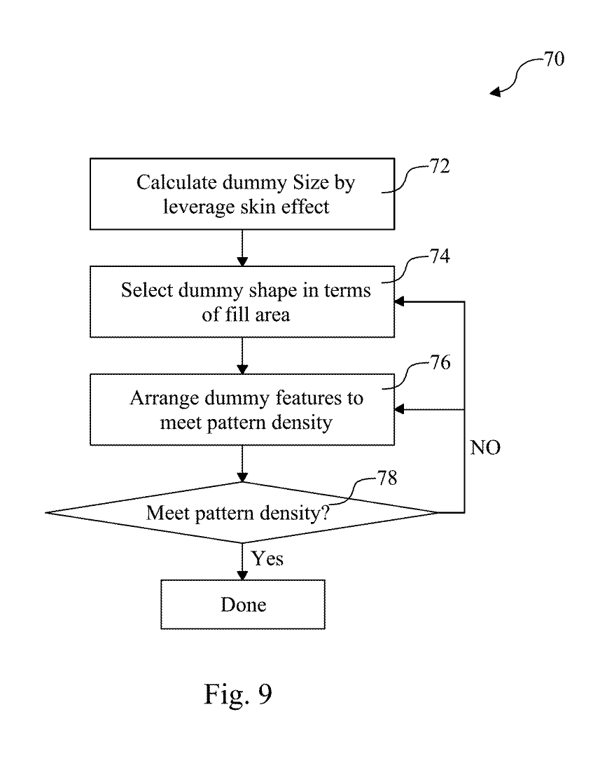

FIG. 9 illustrates a flowchart of a method 70 for insetting dummy features constructed according to aspects of the present disclosure in one or more embodiment. The method 70 is described with reference to FIG. 9 and with further reference to FIGS. 1-8 and 10-18.

The method 70 begins with a design layout of a circuit having an inductor 14. The inductor 14 includes conductive features configured to form a coil with one or more turns. The inductor 14 is designed to be formed on the substrate 12. Various dummy features 30 are to be formed on the substrate 12 and particularly is between the substrate 12 and the inductor 14 to improve pattern uniformity with enhanced reliability. The dummy features 30 are metal features and are configured to be electrically floating.

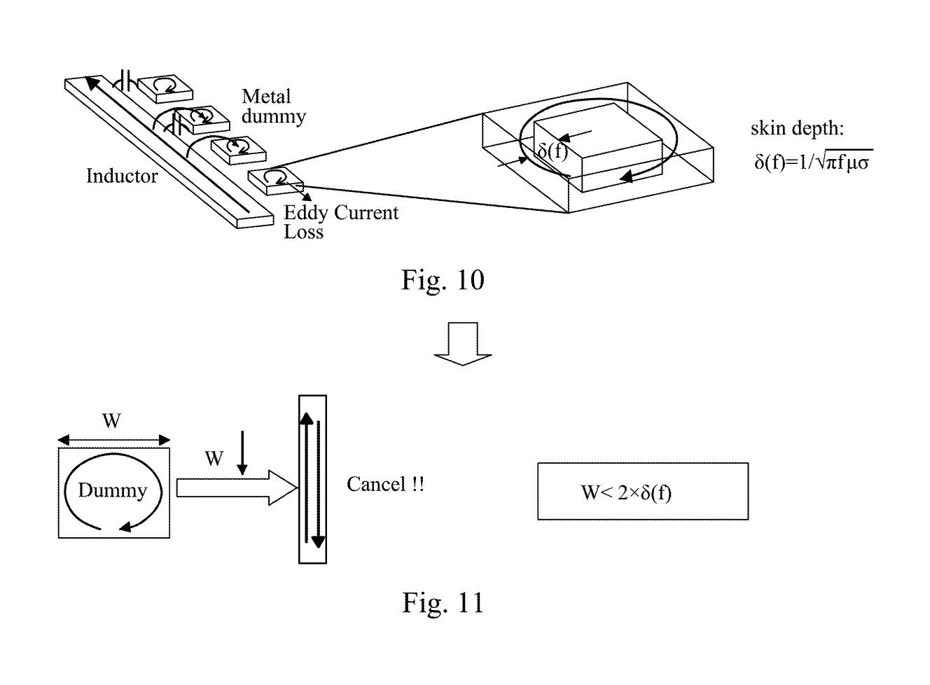

The method 70 includes an operation 72 to determine the size of the dummy features 30 according to the skin effect to avoid or reduce the eddy current. As illustrated in FIG. 10, the inductor during operation will cause eddy current in the dummy features 30. The Eddy current in the dummy features tends to concentrate on the surface, or substantially in the surface with a certain depth, referred to as the skin depth. Therefore, designing the dummy features with proper dimensions based on the skin effect can effectively eliminate or reduce the eddy current. Especially, as illustrated in FIG. 11, when a dummy feature (or a segment of the dummy feature) is designed with the width reduced to a range such that the Eddy current will substantially cancel each other.

This range is associated with the skin depth. As the inductor 14 is designed to be operable to work with a signal (current) of a frequency “f”. The skin depth “δ” is determined by the operation frequency f, or is a function of the frequency f as δ(f). The function of δ(f) is shown in FIG. 10, as δ=1/(πfμσ)^{1/2}, where σ is the resistivity of the dummy features and μ is the absolute magnetic permeability of the dummy features. Each dummy feature includes an elongated segment having a width “w”. The width w is designed to be less than 2 times the skin depth, or w<2×δ(f). By implementing the design of the dummy features with such restrain, the Eddy current is eliminated or substantially reduced. Furthermore, the energy loss in the dummy fills is minimized and the inductor performance is improved. In another embodiment, the thickness T of the dummy features 30 is also designed to be less than 2 times the skin depth, or T<2×δ(f).

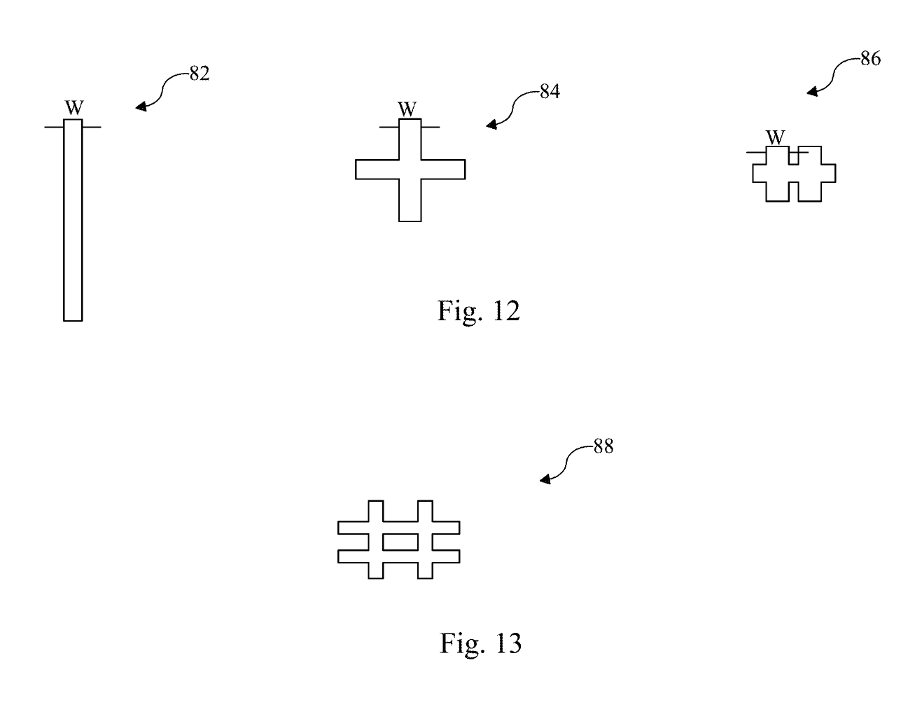

The method 70 includes an operation 74 to determine the shape of the dummy features 30 according to the characteristics of the respective fill area. The dummy features 30 are designed with proper shape according filling regions. In various embodiments illustrated in FIG. 12, the dummy features 30 are designed to have a shape as a rectangle 82, a cross structure 84, a fence structure 86 without closed loop, or combinations thereof. To avoid the Eddy current, any shape with a closed loop, such as a shape 88 illustrated in FIG. 13, is not allowed. In one example, the dummy features filled in a narrow region are designed as rectangle 62. In another example, the dummy features filled in a large and wide region are designed to have a cross shape. In another example, the dummy features filled in a region for higher pattern density are designed to have a fence structure 64.

The method 70 includes an operation 76 to arrange the dummy features according to the pattern density. The arrangement is leveraged to tune the pattern density in order to achieve the uniformity, or meet the expected pattern density. Particularly, the arrangement of the dummy features is optimized to meet the minimum logic metal density rule.

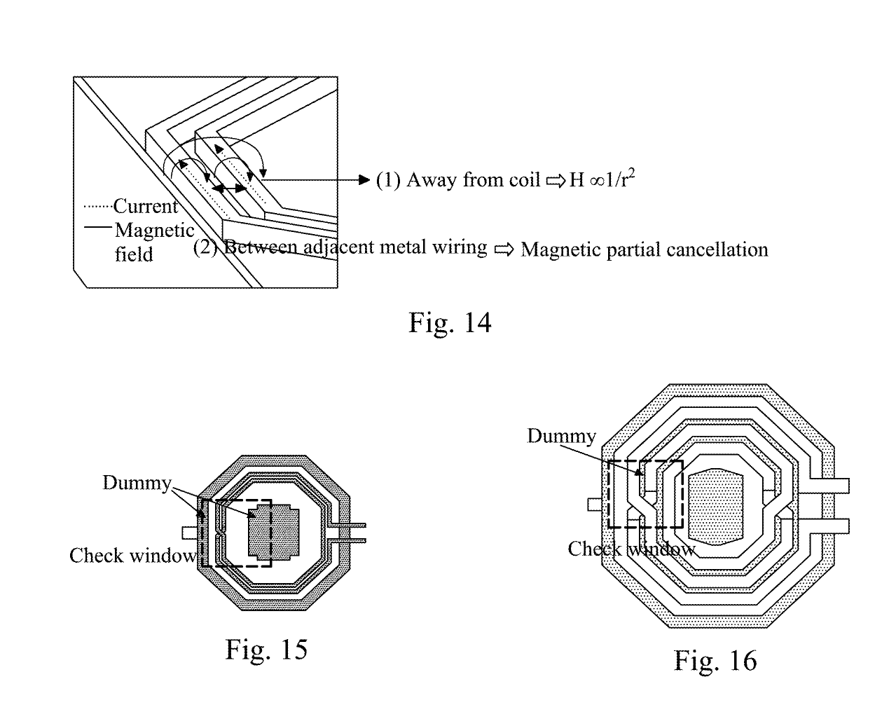

During the arrangement of the dummy features, various factors are considered. As illustrated in FIG. 14, the dummy features are disposed away from the inductor to reduce the parasitic effect since the magnetic field is proportional to 1/r², where r is the distance between the adjacent metal features. Another factor is associated with the configuration of the inductor wiring. When adjacent metal wires of the inductor are properly positioned, the magnetic field can be partially cancelled. The dummy features are disposed in the region with weak magnetic field to induce the parasitic effect.

In one embodiment as illustrated in FIG. 15, when the inductor has a narrower width and less turns, the dummy features are disposed away from the inductor. In one example, the dummy features are not disposed in the gap region(s). In another example, various clearances between the dummy features 30 and the inductor 14 (in the top view) are present to reduce and minimize the parasitic effect. Particularly, the first subset of the dummy features are arranged to have a first clearance to the inductor 14 and the second subset of the dummy features are arranged to have a first clearance to the inductor 14, to reduce and minimize the parasitic effect. The clearance is defined as the horizontal distance between the dummy features and the inductor. In one example, the first clearance and second clearance are equal. In another example, the clearance d is greater than 10 micron.

In one embodiment as illustrated in FIG. 16, when the inductor has a wider width and more turns, the dummy features are disposed in the gap region(s). For example, the dummy features 30 includes a first subset disposed in the inside region 24 and a second subset disposed in the outside region 26, and further includes a third subset disposed in the gap region 28 (or more gap regions when the inductor 14 is configured to form the coil with more turns). By inserting the dummy features in the gap region(s), the pattern density can be further increased.

In another embodiment, the dummy features 30 are arranged in multiple layers to provide a large window for tuning the pattern density.

The method 70 includes an operation 78 to check if the dummy features 30 meet the expected pattern density. If the pattern density is not met, the method 70 proceeds back to the operation 74 or 76 to further tune the shape and arrangement of the dummy features until the pattern density is met. If the pattern density is met, the method 70 is completed with an integrated circuit having the inductor and the dummy metal features designed with the size, shape and configuration.

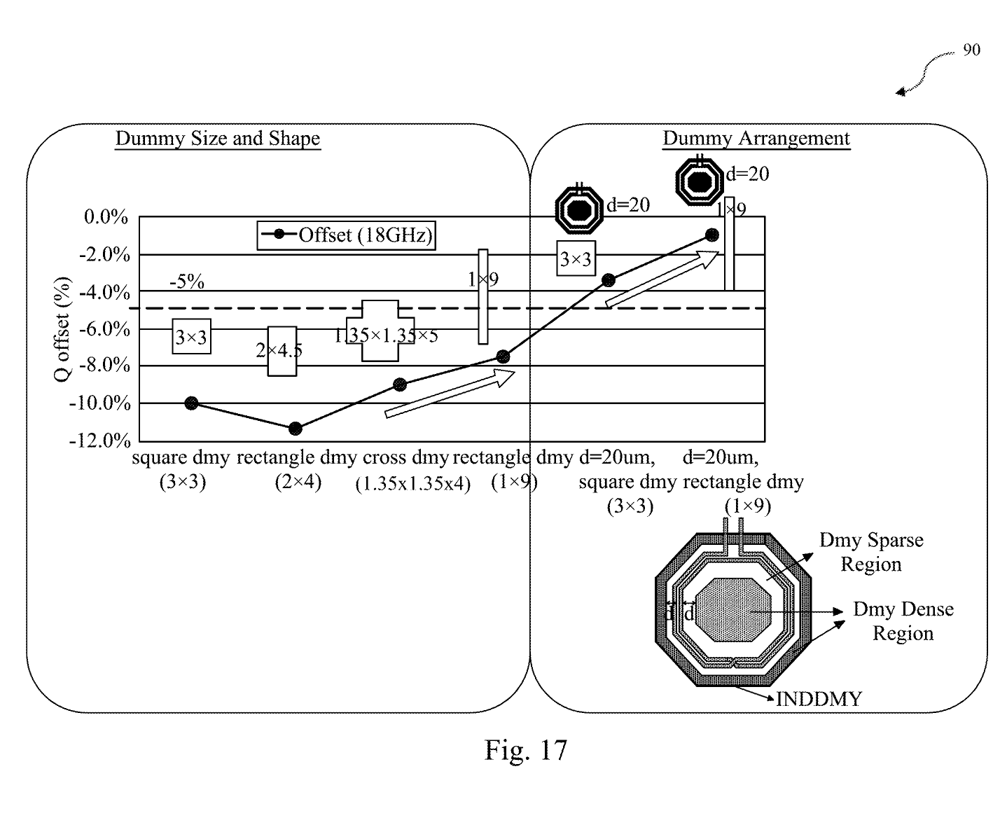

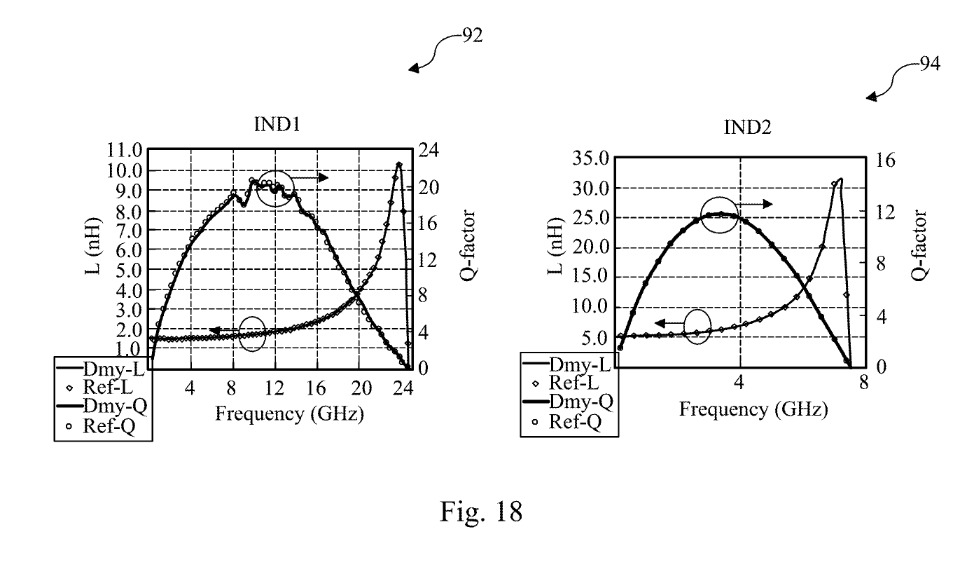

FIG. 17 illustrates a diagram 90 of various simulation results for various dummy features in terms of size, shape and configuration. Those simulation data may be used in the method 70 to assist the design of the dummy features for the corresponding size, shape and configuration. Various data points (represented by symbol “”) correspond respectively to various dummy features “square dmy (3×3)”, “rectangle dmy (2×4)”, “cross dmy (1.35×1.35×4)”, “rectangle dmy (1×9)”, “d=20, square dmy (3×3)”, and “d=20, rectangle dmy (1×9)” as noted below the horizontal axis.

FIG. 18 illustrates various results from the test and measurement for the inductor with or without the dummy features. In FIG. 18, term “dmy” stands for dummy to represent the inductor structure with the dummy features. Term “ref” stands for reference to represent the inductor structure without the dummy features. By using the method 70 to design the dummy features, the pattern uniformity is enhanced while the negative impact of the dummy features to the inductor is minimized in terms of inductance (“L”) and quality factor (“Q-factor”).

The fabrication operations are followed after the completion of the design of the dummy features in the method 70. In one embodiment, the dummy features 30 are formed on a substrate, with the size, shape and configuration determined by the method 70. The inductor 14 is formed on the dummy features 30.

Thus, the present disclosure provides an embodiment of a semiconductor structure that includes an inductor formed on a substrate and configured to be operable with a current of a frequency; and dummy metal features configured between the inductor and the substrate. The dummy metal features include a first width less than 2 times of a skin depth associated with the frequency.

In one embodiment, the dummy metal features have a first thickness less than 2 times of the skin depth, designed to reduce eddy current during operations of the inductor. In another embodiment, the dummy metal features each include an elongated segment having a length, the first width and the first thickness, the first width and first thickness being substantially less than the length.

In another embodiment, the inductor includes inductor metal features having a second thickness and a second width substantially greater than the first thickness and first width, respectively.

In yet another embodiment, in a top view, the inductor includes metal features configured to form at least two turns, defining an inside region, an outside region and a gap region between the two turns; and the dummy metal features include a first subset disposed in the inside region, a second subset disposed in the outside region, and a third subset disposed in the gap region.

In yet another embodiment, the first subset of the dummy metal features is disposed in the inside region with a first clearance to the inductor; and the second subset of the dummy metal features is disposed in the outside region with a second clearance to the inductor. In yet another embodiment, the first and second clearances are equal.

In yet another embodiment, the dummy metal features are configured in a plurality of layers underlying the inductor. In one example, the dummy metal features include a subset having a fence shape without loop. In another example, the dummy metal features include a subset having a rectangle shape.

The present disclosure also provides another embodiment of a semiconductor structure that includes an inductor formed on a substrate and configured to form first and second turns, defining an inside region, an outside region and a gap region between the first and second turns; and dummy metal features configured between the inductor and the substrate. The dummy metal features include a first subset disposed in the inside region, a second subset disposed in the outside region, and a third subset disposed in the gap region, in a top view.

In one embodiment, the inductor is configured to be operable with a current of a frequency; the dummy metal features are designed each having an elongated segment with a width and a thickness; and the width and thickness are less than 2 times of a skin depth as a function of the frequency.

In another embodiment, in the top view, the first turn is inside the second turn; the inside region is inside of the first turn; and the outside region is outside of the second turn. In another embodiment, in a top view, the inductor is configured to further form a third turn between the second turn and the outside region; and the dummy metal features include a fourth subset disposed between another gap region between the second and the third turns.

The present disclosure also provides an embodiment of a method for designing an integrated circuit having an inductor. The method includes determining a size of dummy metal features based on skin effect; determining a shape of the dummy metal features based on filling area; arranging the dummy metal features in a configuration based on pattern density; and defining, in the integrated circuit, the dummy metal features with the size, shape and configuration.

In one embodiment, the determining of a size of the dummy metal features based on skin effect includes determining a dimension of the dummy metal features less than 2 times of a skin depth.

In another embodiment, the determining of a shape of the dummy metal features based on filling area includes choosing a shape selected from the group consisting of rectangle, cross and a fence structure based on the filling area.

In yet another embodiment, the arranging of the dummy metal features based on pattern density includes forming a subset of the dummy metal features in a gap region between adjacent turns of the inductor.

In yet another embodiment, the arranging of the dummy metal features based on pattern density includes inserting a subset of the dummy metal features in a gap region between adjacent turns of the inductor.

In yet another embodiment, the arranging of the dummy metal features based on pattern density includes arranging the dummy metal features in a plurality of layers.

In yet another embodiment, the arranging of the dummy metal features based on pattern density includes arranging a first subset of the dummy metal features in an inside region with a first clearance to the inductor; and arranging a second subset of the dummy metal features in an outside region with a second clearance to the inductor.

In yet another embodiment, the method further includes forming the dummy metal features on a substrate, with the size, shape and configuration; and forming the inductor on the dummy metal features.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

1. A semiconductor structure, comprising:
an inductor formed on a substrate and configured to be operable with a current of a frequency; and
dummy metal features configured between the inductor and the substrate, the dummy metal features having a first width less than 2 times of a skin depth associated with the frequency.

2. The semiconductor structure of claim 1, wherein the dummy metal features have a first thickness less than 2 times of the skin depth, designed to reduce eddy current during operations of the inductor.

3. The semiconductor structure of claim 2, wherein the dummy metal features each include an elongated segment having a length, the first width and the first thickness, the first width and first thickness being substantially less than the length.

4. The semiconductor structure of claim 2, wherein the inductor includes inductor metal features having a second thickness and a second width substantially greater than the first thickness and first width, respectively.

5. The semiconductor structure of claim 2, wherein, in a top view,
the inductor includes metal features configured to form at least two turns, defining an inside region, an outside region and a gap region between the two turns; and
the dummy metal features include a first subset disposed in the inside region, a second subset disposed in the outside region, and a third subset disposed in the gap region.

6. The semiconductor structure of claim 5, wherein
the first subset of the dummy metal features is disposed in the inside region with a first clearance to the inductor; and
the second subset of the dummy metal features is disposed in the outside region with a second clearance to the inductor.

7. The semiconductor structure of claim 6, wherein the first and second clearances are equal.

8. The semiconductor structure of claim 5, wherein the dummy metal features are configured in a plurality of layers underlying the inductor.

9. The semiconductor structure of claim 1, wherein the dummy metal features include a subset having a fence shape without loop.

10. The semiconductor structure of claim 1, wherein the dummy metal features include a subset having a rectangle shape.

11. A semiconductor structure, comprising:
an inductor formed on a substrate and configured to form first and second turns, defining an inside region, an outside region and a gap region between the first and second turns; and
dummy metal features configured between the inductor and the substrate,
wherein the dummy metal features include a first subset disposed in the inside region, a second subset disposed in the outside region, and a third subset disposed in the gap region, in a top view.

12. The semiconductor structure of claim 11, wherein
the inductor is configured to be operable with a current of a frequency;
the dummy metal features are designed each having an elongated segment with a width and a thickness; and
the width and thickness are less than 2 times of a skin depth as a function of the frequency.

13. The semiconductor structure of claim 11, wherein, in the top view,
the first turn is inside the second turn;
the inside region is inside of the first turn; and
the outside region is outside of the second turn.

14. The semiconductor structure of claim 13, wherein, in a top view,
the inductor is configured to further form a third turn between the second turn and the outside region; and
the dummy metal features include a fourth subset disposed between another gap region between the second and the third turns.

15. A method for forming an integrated circuit having an inductor, comprising:
determining a size of dummy metal features based on skin effect;
determining a shape of the dummy metal features based on filling area;
arranging the dummy metal features in a configuration based on pattern density; and
inserting, in the integrated circuit, the dummy metal features with the size, shape and configuration.

16. The method of claim 15, wherein the determining of a size of the dummy metal features based on skin effect includes determining a dimension of the dummy metal features less than 2 times of a skin depth.

17. The method of claim 15, wherein the determining of a shape of the dummy metal features based on filling area includes choosing a shape selected from the group consisting of rectangle, cross and a fence structure based on the filling area.

18. The method of claim 15, wherein the arranging of the dummy metal features based on pattern density includes forming a subset of the dummy metal features in a gap region between adjacent turns of the inductor.

19. The method of claim 15, wherein the arranging of the dummy metal features based on pattern density includes inserting a subset of the dummy metal features in a gap region between adjacent turns of the inductor.

20. The method of claim 15, wherein the arranging of the dummy metal features based on pattern density includes arranging the dummy metal features in a plurality of layers.

21. The method of claim 15, wherein the arranging of the dummy metal features based on pattern density includes
arranging a first subset of the dummy metal features in an inside region with a first clearance to the inductor; and
arranging a second subset of the dummy metal features in an outside region with a second clearance to the inductor.

22. The method of claim 15, further comprising:
forming the dummy metal features on a substrate, with the size, shape and configuration; and
forming the inductor on the dummy metal features.
